(19) United States
(12) Patent Application Publication
(10) Pub. No.: US 2008/0266217 A1
(43) Pub. Date: Oct. 30, 2008

(54) DRIVING INTEGRATED CIRCUIT, LIQUID CRYSTAL DISPLAY, DISPLAY SYSTEM AND METHOD OF DRIVING AN INTEGRATED CIRCUIT

(75) Inventor: Jong-woo KIM, Anyang-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/779,377

(22) Filed: Jul. 18, 2007

(30) Foreign Application Priority Data
Aug. 3, 2006 (KR) 10-2006-0073492

(51) Int. Cl. G09G 3/36; H03K 3/00

(52) U.S. Cl. 345/87; 327/108

(57) ABSTRACT

A driving IC including; an interface unit which receives an external data signal from the outside and outputs an internal data signal, at least one reference voltage output unit which receives the internal data signal and outputs a first reference voltage corresponding to the internal data signal, and at least one common voltage output unit which receives a voltage from a common electrode and the first reference voltage, compares the first reference voltage and the voltage from the common electrode, and which outputs a common voltage based on the comparison result.

This application claims priority to Korean Patent Application No. 10-2006-0073492, filed on Aug. 3, 2006, and all the benefits accruing therefrom under 35 U.S.C. § 119, the contents of which in its entirety are herein incorporated by reference.

### BACKGROUND OF THE INVENTION

1. Field of the Invention

The present invention relates to a driving integrated circuit (“IC”), a liquid crystal device, a display system, and method of driving an integrated circuit.

2. Description of the Related Art

A liquid crystal device includes a first substrate on which pixel electrodes and thin film transistors are formed, a second substrate on which a common electrode and color filters are formed, and a liquid crystal layer interposed therebetween. The liquid crystal layer is twisted on the basis of a potential difference between the pixel electrode of the first substrate and the common electrode of the second substrate. The twisting caused by the voltage difference between the pixel electrode and the common electrode varies the transmittance of light through the liquid crystal layer. A data voltage is applied to the pixel electrode and a common voltage is applied to the common electrode. In order to increase the longevity of the liquid crystal molecules the voltage difference applied to the electrodes on opposite sides of the liquid crystal layer is constantly varied. At one point in time a positive voltage may be applied to the pixel electrode and at another point in time a negative voltage may be applied to the pixel electrode, wherein both voltages differ from the voltage of the common electrode by the same magnitude. This is accomplished by applying a positive image data voltage and a negative image data voltage to the pixel electrode on the basis of the common voltage. The positive image data voltage and the negative image data voltage do not have to be positive and negative voltages, respectively, as long as they vary above and below the common voltage by the same magnitude; e.g., if the common voltage is 10 V, the positive image data voltage may be 15 V and the negative image data may be 5 V.

However, a flicker may occur due to a kickback phenomenon, the kickback phenomenon being caused by a kickback voltage generated due to the characteristics of the switching element and a parasitic capacitance, and the voltage of the common electrode to which the common voltage is applied may be distorted due to the reaction of a liquid crystal capacitor connected thereto, thereby causing deterioration of display quality. Differences between a gate-on voltage and a gate-off voltage for each switching element vary with distances along gate lines which drive the switching elements. It is this variation which causes the kickback phenomenon and the associated unwanted flicker. The voltage stored in the liquid crystal capacitor does not react instantly to changes in the voltage of a pixel electrode connected thereto, thereby causing distortion in the transmittance level of the display. Accordingly, it is necessary to reduce both the flicker of the display and the distortion of the voltage of the common electrode in order to improve display quality.

### BRIEF SUMMARY OF THE INVENTION

An aspect of the present invention is to provide a driving IC which improves display quality.

Another aspect of the invention is to provide a liquid crystal display device which improves display quality.

Still another aspect of the invention is to provide a display system which adjusts a common voltage to improve display quality.

Still another aspect of the invention is to provide a method of driving an integrated circuit which adjusts a common voltage to improve display quality.

According to an exemplary embodiment of the present invention, a driving IC includes; an interface unit which receives an external data signal from an outside and outputs an internal data signal, at least one reference voltage output unit which receives the internal data signal and outputs a first reference voltage corresponding to the internal data signal, and at least one common voltage output unit which receives a voltage from a common electrode and the first reference voltage, compares the first reference voltage and the voltage from the common electrode, and which outputs a common voltage based on the comparison result.

According to another exemplary embodiment of the present invention, a liquid crystal display device includes a liquid crystal panel assembly which includes a first substrate which includes a pixel electrodes and a second substrate which includes a common electrode, and a driving unit which includes a memory which outputs an internal data signal, a digital to analog converter which receives the internal data signal and which outputs a first reference voltage corresponding to the internal data signal, and at least one common voltage output unit which receives the voltage of the common electrode and which compares the first reference voltage and the voltage of the common electrode and outputs a common voltage based on the comparison result.

According to another exemplary embodiment of the present invention, a display system includes; an external signal supply device which supplies an external data signal, and a driving device which includes a liquid crystal panel assembly including a first substrate on which pixel electrodes are formed and a second substrate on which a common electrode is formed, and a driving device including; an interface unit which receives the external data signal and outputs an internal data signal, at least one reference voltage output unit which receives the internal data signal and outputs a first reference voltage corresponding to the internal data signal, and at least one common voltage output unit which receives the first reference voltage, compares the first reference voltage and a voltage of the common electrode, and outputs a common voltage based on the comparison result.

According to another exemplary embodiment of the present invention a method of driving an integrated circuit includes; converting an external data signal to an internal data signal and providing the internal data signal to at least one reference output voltage unit, converting the internal data signal to a first reference voltage and outputting the first reference voltage to at least one common voltage output unit, comparing the first reference voltage and a voltage from a common electrode, and outputting a common voltage based on the comparison result.

### BRIEF DESCRIPTION OF THE DRAWINGS

The above and other aspects, features and advantages of the present invention will become more apparent by describing in more detail exemplary embodiments thereof with reference to the attached drawings, in which:

FIG. 1 is a block diagram showing an exemplary embodiment of a display system according to the present invention;

FIG. 2 is an equivalent circuit diagram of an exemplary embodiment of a pixel in the exemplary embodiment of a liquid crystal display device shown in FIG. 1;

FIG. 3 is an equivalent circuit diagram illustrating a cause of a flicker phenomenon;

FIG. 4 is a graph showing an external data signal applied to the exemplary embodiment of a display system shown in FIG. 1;

FIG. 5 is a graph showing an internal data signal and a clock signal of the exemplary embodiment of a display system shown in FIG. 1;

FIG. 6 is a circuit diagram showing in more detail an exemplary embodiment of a reference voltage output unit of the exemplary embodiment of a display system as shown in FIG. 1;

FIG. 7A is a circuit diagram showing an exemplary embodiment of a common voltage output unit of the exemplary embodiment of a display system as shown in FIG. 1;

FIG. 7B is a circuit diagram showing another exemplary embodiment of a common voltage output unit of the exemplary embodiment of a display system as shown in FIG. 1;

FIG. 8 is a graph illustrating the variation of voltage with time of a capacitor shown in FIGS. 7A and 7B;

FIG. 9 is a graph illustrating the variation of voltage with time of a common voltage output from an exemplary embodiment of the common voltage output unit shown in FIGS. 7A and 7B;

FIG. 10 is a block diagram showing another exemplary embodiment of a display system according to the present invention; and

FIG. 11 is a block diagram showing another exemplary embodiment of a liquid crystal display device according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

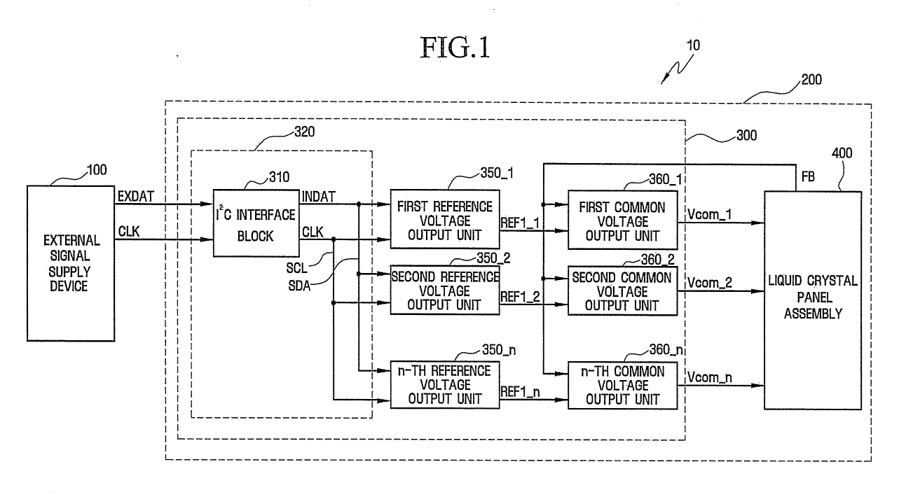

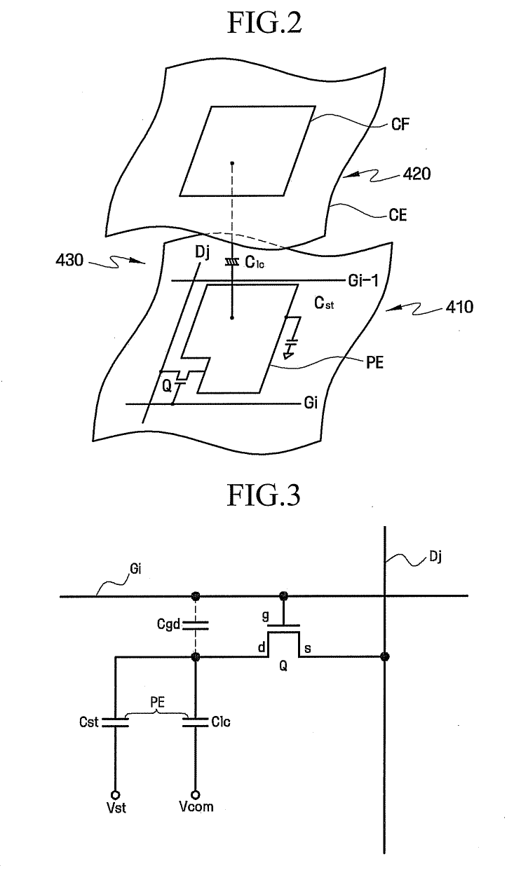

FIG. 1 is a block diagram showing an exemplary embodiment of a display system according to the present invention, and FIG. 2 is an equivalent circuit diagram of an exemplary embodiment of a pixel in the exemplary embodiment of a liquid crystal display device shown in FIG. 1.

Referring to FIG. 1, an exemplary embodiment of a display system 10 according to the present invention includes an external signal supply device 100 and a liquid crystal display device 200. The liquid crystal display device 200 includes a driving integrated circuit (“IC”) 300 and a liquid crystal panel assembly 400.

When the external signal supply device 100 supplies an external data signal EXDAT and a clock signal CLK to the liquid crystal display device 200, the driving IC 300 outputs a plurality of common voltages Vcom_1 to Vcom_n using a voltage FB of a common electrode fed-back from the liquid crystal panel assembly 400. The driving IC 300 internally generates first reference voltages REF_1 to REF_n corresponding to the external data signal EXDAT.

Each of the output common voltages Vcom_1 to Vcom_n has a direct current component or an alternating current component. The direct current components correspond to the first reference voltages REF_1 to REF_n and the alternating current component is generated using the fed-back voltage FB of the common electrode. Here, the first reference voltages REF_1 to REF_n having the direct current components correspond to the external data signal EXDAT supplied from the external signal supply device 100, which will reduce the flicker phenomenon (described in more detail below) and the alternating component corresponds to the voltage FB of the common electrode, which will reduce distortion of each of the common voltages Vcom_1 to Vcom_n (described in more detail below).

In one exemplary embodiment the display system 10 may be a test system for the liquid crystal display device 200. That is, when a manufacturer performs a test for the liquid crystal display device 200, the external data signal EXDAT is supplied to the liquid crystal display device 200 through the external signal supply device 100 so as to output the common voltages Vcom_1 to Vcom_n, which minimize the flicker phenomenon before the liquid crystal display device is used by the user. Otherwise, when a user uses the liquid crystal display device 200, the user supplies the external data signal EXDAT to the liquid crystal display device 200 through the external signal supply device 100 and adjusts the common voltages Vcom_1 to Vcom_n so as to improve display quality. In either of these exemplary embodiments, the external signal supply device 100 may be a computer.

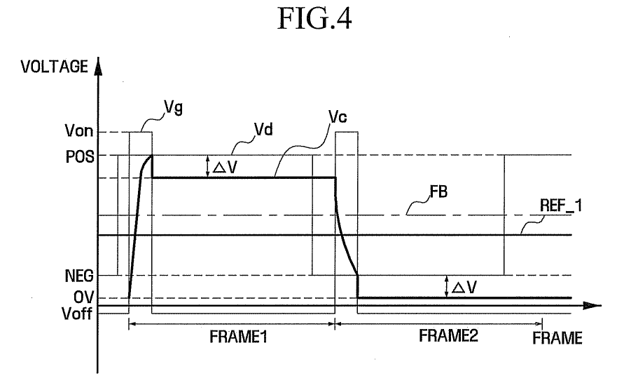

Hereinafter, each functional block will be described in detail. First, in order to reduce the flicker of the liquid crystal display device 200, the external signal supply device 100 supplies the external data signal EXDAT. The manufacturer or the user, among others, may supply the external data signal EXDAT to the liquid crystal display device 200 using the external signal supply device 100 so as to reduce the flicker of the liquid crystal display device 200. The external data signal EXDAT and the flicker will be described below with reference to FIGS. 3 and 4.

The driving IC 300 receives the external data signal EXDAT and a clock signal CLK and outputs a plurality of common voltages Vcom_1 to Vcom_n corresponding to the external data signal EXDAT.

The driving IC 300 includes an interface unit 320, one or more reference voltage output units 350_1 to 350_{—}n, and one or more common voltage output units 360_1 to 360_{—}n, wherein n is a positive whole number. Hereinafter, it is assumed that the driving IC 300 includes n reference voltage output units 350_1 to 350_{—}n and n common voltage output units 360_1 to 360_{—}n.

The interface unit 320 converts the external data signal EXDAT to an internal data signal INDAT and supplies it in series to the plurality of reference voltage output units 350_1 to 350_{—}n. Here, the interface unit 320 may comprise an inter integrated circuit 310 (hereinafter, referred to as “I²C”) which is a kind of serial digital interface. The conversion from EXDAT to INDAT is discussed in more detail below.

The I²C interface is a two-wire interface and includes a serial data line SDA for performing data communication between a master and a slave, and a serial clock line SCL for controlling and synchronizing the communication between the master and the slave.

That is, the external signal supply device 100, which functions as the master, supplies the external data signal EXDAT through a serial data line SDA and supplies the clock signal CLK through a clock line SCL. In the present exemplary embodiment, the internal data signal INDAT supplied to the plurality of reference voltage output units 350_1 to 350_{—}n, which function as slaves, is supplied through one serial data line SDA in series. This kind of data transmission is called a series interface. The plurality of reference voltage output units 350_1 to 350_{—}n which function as the slave are synchronized by the clock signal CLK and receive the internal data signal INDAT supplied through the serial data line SDA.

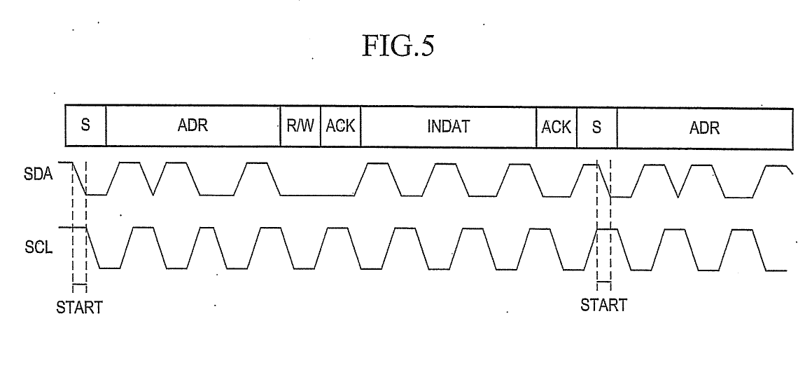

In the present exemplary embodiment the I²C interface block 310 converts the external data signal EXDAT into the internal data signal INDAT which can be processed by the plurality of reference voltage output units 350_1 to 350_{—}n. In one exemplary embodiment, the I²C interface block 310 converts the external data signal EXDAT into an internal data signal INDAT comprising a transistor-transistor logic (“TTL”) signal. However, the interface unit 320 may comprise the serial data line SDA and the serial clock line SCL without the I²C interface block 310. In such an exemplary embodiment, the external data signal EXDAT may be the same as the internal data signal INDAT. The internal data signal INDAT and the clock signal CLK will be described below with reference to FIG. 5.

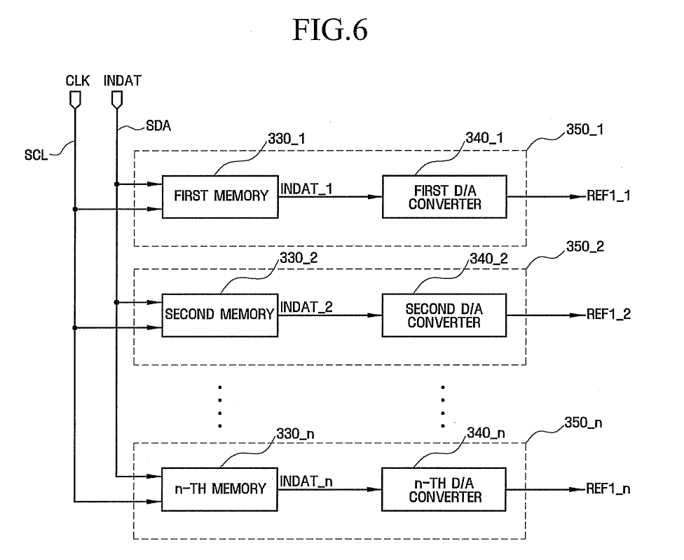

Meanwhile, the plurality of reference voltage output units 350_1 to 350_{—}n respectively output first reference voltages REF_1 to REF_n with respect to the internal data signal INDAT supplied from the external signal supply device 100. The reference voltage output units 350_1 to 350_{—}n may respectively comprise digital/analog converters 340_1 to 340_{—}n which output the first reference voltages REF_1 to REF_n of an analog voltage and correspond to the internal data signal INDAT as will be discussed in more detail with reference to FIG. 6.

Here, the first reference voltages REF_1 to REF_n have a voltage level which reduces a flicker, which becomes the direct current component of each of the common voltages Vcom_1 to Vcom_n output from the individual common voltage output units 360_1 to 360_{—}n. An internal circuit of each of the reference voltage output units 350_1 to 350_{—}n and the operation thereof will be described below with reference to FIG. 6.

Each of the plurality of common voltage output units 360_1 to 360_{—}n receives the voltage FB of the common electrode fed-back from the common electrode of the liquid crystal panel assembly 400, and compares each of the first reference voltages REF_1 to REF_n and the voltage FB of the common electrode. According to the comparison result, each of the common voltage output units 360_1 to 360_{—}n outputs a corresponding one of common voltages Vcom_1 to Vcom_n. In particular, each of the common voltage output units 360_1 to 360_{—}n generates a direct alternating current component on the basis of the fed-back voltage FB of the common electrode and mixes the generated alternating current component with the direct current provided by each of the first reference voltages REF_1 to REF_n.

In order to show moving images the display must rapidly show a succession of individual images, also called “frames”. When seen together in succession, the rapid display of a plurality of frames creates the illusion of a moving image. When an image data voltage having a different polarity for each frame is applied to the pixel electrode of the liquid crystal panel assembly 400, the voltage FB of the common electrode of the liquid crystal panel assembly 400 is distorted due to a capacitance component between the pixel electrode and the common electrode. That is, the voltage FB of the common electrode is coupled with the image data voltage applied to the pixel electrode due to a liquid crystal capacitor. As a result, the voltage FB of the common electrode is distorted, e.g., non-constant. Here, the distortion component is a direct current type of distortion. Therefore, the alternating current component having an inverse phase with respect to the distortion component needs to be generated and mixed with each of the first reference voltages REF_1 to REF_n so as to output the common voltages Vcom_1 to Vcom_n to decrease flicker and distortion. That is, each of the first reference voltages REF_1 to REF_n is modified and each of the common voltages Vcom_1 to Vcom_n is output such that the voltage FB of the common electrode can be held constant by the first reference voltages REF_1 to REF_n even though the voltage FB of the common electrode is degraded due to the distortion caused by coupling of the voltage FB and the image data voltage.

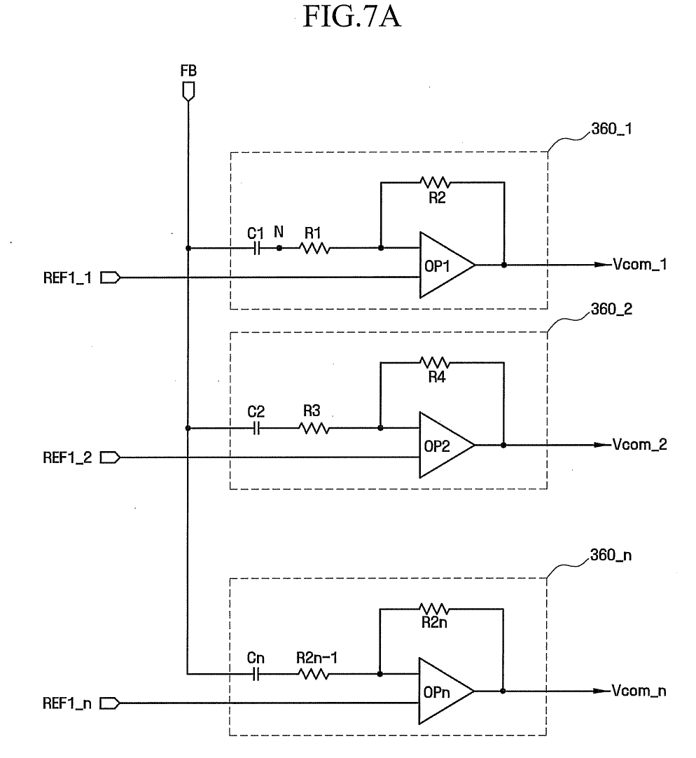

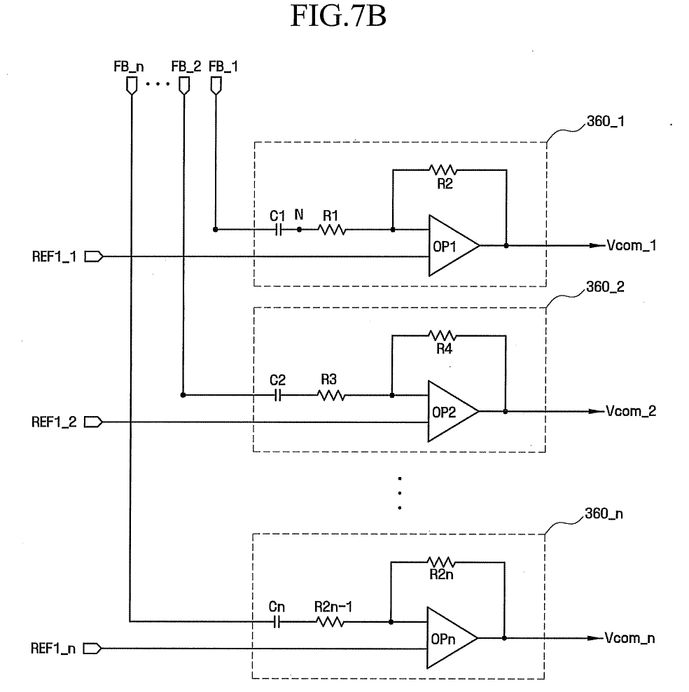

A process of outputting each of the common voltages Vcom_1 to Vcom_n using an individual internal circuit of each of the common voltage output units 360_1 to 360_{—}n and the fed-back voltage FB of the common electrode will be described below with reference to FIGS. 7A and 7B. Meanwhile, FIG. 1 shows an exemplary embodiment where one voltage FB of the common electrode is fed-back from the liquid crystal panel assembly 400 and supplied to each of the common voltage output units 360_1 to 360_{—}n. However, the present invention is not limited thereto and alternative exemplary embodiments include configurations wherein each of the common voltage output units 360_1 to 360_{—}n may receive the voltage FB from different parts of the common electrode. This alternative exemplary embodiment is especially useful in that the voltage FB may vary at each part of the common electrode.

The liquid crystal panel assembly 400 returns the voltage FB of the common electrode to each of the common voltage output units 360_1 to 360_{—}n, receives the common voltages Vcom_1 to Vcom_n, and displays an image.

Referring to FIG. 2, one pixel of the liquid crystal panel assembly 400 includes a first panel 410 on which thin film transistors (“TFTs”) and pixel electrodes PE are formed, a second panel 420 on which a common electrode CE is formed, and a liquid crystal layer 430 interposed therebetween.

A color filter CF may be partially formed in a region of the common electrode CE of the second panel 420 so as to face the pixel electrode PE of the first panel 410. The pixel includes a switching element Q connected between an i-th gate line Gi and a j-th data line Dj, a liquid crystal capacitor Clc connected to the switching element Q, and a storage capacitor Cst. Alternative exemplary embodiments include configurations wherein the storage capacitor Cst may be omitted.

When the common voltages Vcom_1 to Vcom_n supplied from the driving IC 300 are applied to the common electrode of the liquid crystal panel assembly 400, the flicker phenomenon is reduced. Even though an image data voltage having a different polarity is applied, the voltage FB of the common electrode is not distorted, thereby improving display quality.

Here, the flicker and the external data signal supplied to reduce the flicker will be described with reference to FIGS. 3 and 4. FIG. 3 is a circuit diagram illustrating a flicker and FIG. 4 is a graph showing an external data signal shown in FIG. 1.

FIG. 3 is an equivalent circuit diagram illustrating the cause of a flicker phenomenon. The equivalent circuit of FIG. 3 includes a pixel which includes a switching element Q, a parasitic capacitor Cgd formed between a drain electrode d of the switching element Q and a j-th data line Dj, a liquid crystal capacitor Clc formed between a pixel electrode PE and a common electrode, and a storage capacitor Cst formed between the pixel electrode PE and a storage electrode to which a storage voltage Vst is applied.

FIG. 4 is a graph showing an external data signal applied to the exemplary embodiment of a display system shown in FIG. 1. The graph shows a gate signal Vg, a data signal Vd, a pixel electrode voltage Vc, a voltage FB of the common electrode, and a first reference voltage REF_1, which are applied to the pixel PX shown in FIG. 3 in two continuous frames. Here, the external data signal EXDAT for reducing the flicker will be described. For convenience of explanation, the distortion phenomenon of the voltage FB of the common electrode is not considered. The direct current component of the voltage FB of the common electrode and the first reference voltage REF_1 having the direct current component of the common voltage Vcom_1 are shown.

The gate signal Vg is a gate on/off voltage Von/Voff and is sequentially supplied to the i-th gate line Gi shown in FIG. 3 for every frame. The data signal Vd has a positive image data voltage POS in a first frame FRAME1 and becomes a negative image data voltage NEG in a second frame FRAME2. The data signal Vd is supplied to the pixel electrode PE (see FIG. 3) through the j-th data line Dj.

In particular, when the positive image data voltage POS is applied to the pixel electrode PE in the first frame FRAME1, the pixel electrode voltage Vc substantially equals the positive image data voltage POS. If the gate-off-voltage Voff is applied to the gate electrode g of the switching element Q, the voltage of the gate electrode g is quickly lowered and coupled to the parasitic capacitor Cgd. As a result, the pixel electrode voltage Vc decreases. Due to this kickback phenomenon, the pixel electrode voltage Vc becomes lower than the positive image data voltage POS by a kickback voltage ΔV.

In the same manner, the pixel electrode voltage Vc is decreased by the kickback voltage ΔV to become lower than the negative image data voltage NEG in the second frame FRAME2.

That is, the pixel electrode voltage Vc of the liquid crystal panel assembly 400 is reduced by a predetermined level due to the kickback phenomenon. Therefore, a root mean square (“RMS”) value of the positive image data voltage POS becomes different from a RMS value of the negative image data voltage NEG on the basis of the voltage FB of the common electrode, such that the flicker occurs. In other words, the absolute magnitude of the difference between the positive image data voltage POS and the voltage FB of the common electrode is different from the absolute magnitude of the difference between the negative image data voltage NEG and the voltage FB of the common electrode. In the exemplary embodiment shown in FIG. 4 the voltage of the positive image data is brought closer to the voltage FB of the common electrode and the negative image data is pushed farther away from the voltage FB of the common electrode; thereby the magnitude of voltage difference between image data and the common electrode in consecutive frames varies. This variation in image data will allow the light transmittance of the display device in one frame to vary from the light transmittance of the display device in a consecutive frame, this unwanted transmittance variation from frame to consecutive frame is the flicker phenomenon.

According to an exemplary embodiment of the present invention the first reference voltage REF_1 equalizes the RMS value of the positive image data voltage POS and the RMS value of the negative image data voltage NEG. The first reference voltage REF_1 is an analog voltage which corresponds to the external data signal EXDAT. That is, a manufacturer or a user supplies the external data signal EXDAT corresponding to the first reference voltage REF_1 to the liquid crystal display device 200 through the external signal supply device 100 (see FIG. 1) in order to reduce the flicker. Therefore, it is possible to reduce the flicker and improve display quality of the liquid crystal display device 200 (see FIG. 1).

A method of transmitting the internal data signal and the clock signal used to reduce the flicker will be described with reference to FIG. 5. FIG. 5 is a graph showing the internal data signal and the clock signal of the exemplary embodiment of a display system shown in FIG. 1.

Referring to FIG. 5, a signal on the serial data line SDA includes a start signal S, an address signal ADR, an answer signal ACK, a read/write signal R/W, and an internal data signal INDAT.

In particular, when the clock signal CLK is in a high level and the start signal S changes from a high level to a low level, the transmission of the address signal ADR, answer signal ACK, read/write signal R/W, and internal data signal INDAT starts.

The address signal ADR is a signal for designating one among the plurality of reference voltage output units 350_1 to 350_{—}n. That is, a 7-bit address signal can designate 128 (2⁷) reference voltage output units 350_1 to 350_{—}n.

The read/write signal R/W notifies a data transmission direction between the external signal supply device 100 and the reference voltage output units 350_1 to 350_{—}n. According to the present exemplary embodiment of the invention, since the external signal supply device 100 supplies the internal data signal INDAT to the plurality of reference voltage output units 350_1 to 350_{—}n, in case of a write operation, the clock signal CLK may be in a low level.

The answer signal ACK is a signal for notifying one of the reference voltage output units 350_1 to 350_{—}n which is designated by the address signal ADR and notifying the external signal supply device 100 whether or not other reference voltage output units 350_1 to 350_{—}n are designated by the address signal. For example, a first reference voltage output unit 350_1 designated by one address signal ADR transmits an answer signal ACK in a low level to the external signal supply device 100 and other reference voltage output units 350_2 to 350_{—}n transmit answer signals ACK in a high level to the external signal supply device 100.

Continuing the example provided above, when the external signal supply device 100 receives an answer signal ACK in a low level, the external signal supply device 100 transmits an internal data signal INDAT to the corresponding reference voltage output unit 350_1 until the answer signal ACK in a low level is received. When the external signal supply device 100 receives an answer signal ACK in a high level, the external signal supply device 100 stops transmitting the internal data signal INDAT and supplies a start signal S, an address signal ADR, or the like so as to transmit the internal data signal INDAT to other reference voltage output units 350_2 to 350_{—}n.

Even though the interface unit 320 has been described with reference to the exemplary embodiment wherein the interface unit 320 comprises the I²C interface, alternative exemplary embodiments include configurations wherein the interface unit 320 may be configured by a serial peripheral interface (hereinafter, refer to as “SPI”), which is a 3-wire interface. Though not shown in the drawings, the SPI interface includes a first serial data line for data transmission, a second serial data line for receiving data, and a serial clock line for synchronization.

The reference voltage output unit 350 which processes the internal data signal supplied from the interface unit will be described in more detail with reference to FIG. 6. FIG. 6 is a circuit diagram showing in more detail an exemplary embodiment of the reference voltage output unit of the exemplary embodiment of a display system as shown in FIG. 1.

Referring to FIG. 6, the reference voltage output units 350_1 to 350_{—}n respectively includes memories 330_1 to 330_{—}n and digital/analog converters 340_1 to 340_{—}n.

Turning now to the problem of common voltage distortion, each of the memories 330_1 to 330_{—}n receives the internal data signal INDAT from the external signal supply device 100 and stores the received internal data signal INDAT. Therefore, even when the external signal supply device 100 does not supply the external data signal EXDAT, the memories 330_1 to 330_{—}n supply the internal data signal INDAT to the digital/analog converters 340_1 to 340_{—}n, respectively, the first reference voltages REF_1 to REF_n are continuously output.

In FIG. 6, the first to n-th memories 330_1 to 330_{—}n are functionally separated. However exemplary embodiments include configurations wherein the first to n-th memories 330_1 to 330_{—}n are physically separated and configurations wherein any of the first to n-th memories 330_1 to 330_{—}n are physically connected. Each of the memories 330_1 to 330_{—}n stores a 7-bit internal data signal INDAT corresponding to the I²C system and each of the memories 330_1 to 330_{—}n may be a nonvolatile memory. In one exemplary embodiment each of the memories 330_1 to 330_{—}n may be an electrically erasable programmable read-only memory (“EEPROM”).

The digital/analog converters 340_1 to 340_{—}n correspondingly output analog voltage type first reference voltages REF_1 to REF_n corresponding to the internal data signal INDAT. That is, the internal data signal INDAT used to reduce the flicker is converted into the respective first reference voltages REF_1 to REF_n and each of the first reference voltages REF_1 to REF_n becomes a direct current component of each of the common voltages Vcom_1 to Vcom_n.

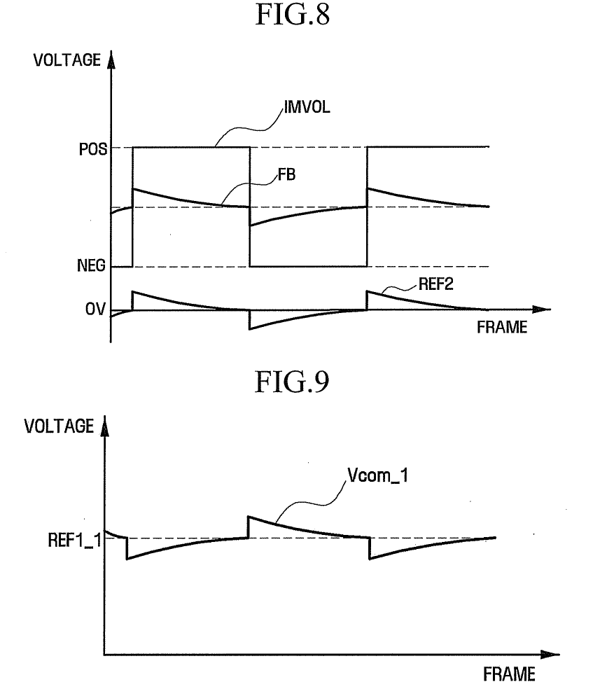

Here, the common voltage output unit which outputs a common voltage using the first reference voltage having a direct current component and an alternating current component corresponding to the fed-back voltage of the common electrode will be described with reference to FIGS. 7A to 9. FIG. 7A is a circuit diagram showing an exemplary embodiment of the common voltage output unit of the exemplary embodiment of a display system as shown in FIG. 1. FIG. 7B is a circuit diagram showing another exemplary embodiment of a common voltage output unit of the exemplary embodiment of a display system as shown in FIG. 1. FIG. 8 is a graph illustrating the variation of voltage with time of a capacitor shown in FIGS. 7A and 7B. FIG. 9 is a graph illustrating the variation of voltage with time of a common voltage output from an exemplary embodiment of the common voltage output unit shown in FIGS. 7A and 7B.

Referring to FIG. 7A, the common voltage output units 360_{—}1 to 360_{—}n respectively include capacitors C1 to Cn, operation amplifiers OP1 to OPn, and a plurality of resistors R1 to R2n.

The distorted voltage FB of the common electrode is fed-back from the liquid crystal panel assembly 400 and supplied to the respective common voltage output units 360_1 to 360_{—}n. The distorted voltage FB arises due to the reaction of the liquid crystal capacitor to changes in the applied pixel electrode voltages.

Otherwise, as shown in FIG. 7B, each of the common voltage output units 360_1 to 360_{—}n may receive a corresponding voltage FB_1, FB_2, . . . , FB_n of the common electrode at a plurality of parts of the common electrode. Preferably, each of the respective voltage FB_1, FB_2, . . . , FB_n of the common electrode may be fed-back from a position at which each of the common voltages Vcom_1 to Vcom_n is applied to the corresponding common voltage output units 360_1 to 360_{—}n.

Referring to FIG. 8, the voltage FB of the common electrode is coupled to the image data voltage IMVOL and is distorted thereby. In particular, if the positive image data voltage POS is applied to a pixel electrode, the voltage FB of the common electrode rises due to change in the charge of the liquid crystal capacitor Clc (see FIG. 2). If the negative image data voltage NEG is applied to a pixel electrode, the voltage FB of the common electrode drops due to the change in the charge of the liquid crystal capacitor. The voltage FB of the common electrode is distorted as shown in FIG. 8.

The capacitor C1-Cn of each of the common voltage output units 360_1 to 360_{—}n, respectively supplies a second reference voltage REF2 having the distorted direct current component of the voltage FB of the common electrode to each of the operation amplifiers OP1 to OPn. That is, the voltage at the second reference voltage node N (see FIGS. 7A and 7B) becomes the second reference voltage REF2.

As shown in FIG. 9, each of the operation amplifiers OP1 to OPn amplifies a difference between the second reference voltage REF2 and each of the first reference voltage REF1_1 to REF1_{—}n supplied from the corresponding reference voltage output units 350_1 to 350_{—}n and outputs the common voltages Vcom_1 to Vcom_n. That is, each of the common voltages Vcom_1 to Vcom_n is obtained by subtracting the second reference voltage REF2 from each of the direct-current first reference voltages REF1_1 to REF1_{—}n.

When the common voltages Vcom_1 to Vcom_n are supplied to the liquid crystal panel assembly 400, even though the liquid crystal capacitor Clc (see FIG. 2) causes distortion, the distortion is offset with the common voltages Vcom_1 to Vcom_n such that the voltage FB of the common electrode may be kept at the same level as the first reference voltages REF_1 to REF_n. That is, the voltage FB of the common electrode is held to a predetermined direct current voltage level.

Accordingly, the flicker does not occur and the voltage FB of the common electrode is not distorted and kept to the predetermined direct current voltage. As a result, it is possible to improve display quality of the liquid crystal display device 200 (see FIG. 1).

According to the display system 10 (see FIG. 1), the common voltages Vcom_1 to Vcom_n may be easily adjusted to improve display quality. In another exemplary embodiment the number of reference voltage output units 350_1 to 350_ and the number of common voltage output units 360_1 to 360_{—}n (see FIG. 1) are increased and it is possible to gain superior display quality. In this exemplary embodiment, the common voltages Vcom_1 to Vcom_n may be easily adjusted.

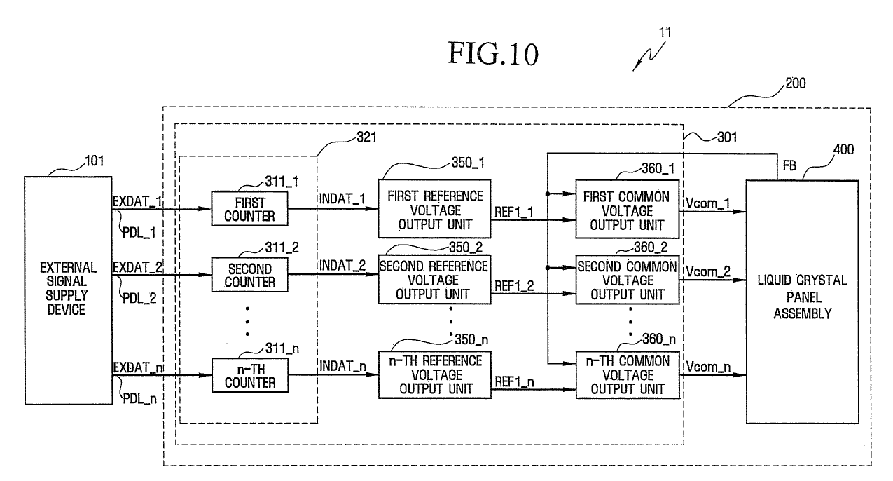

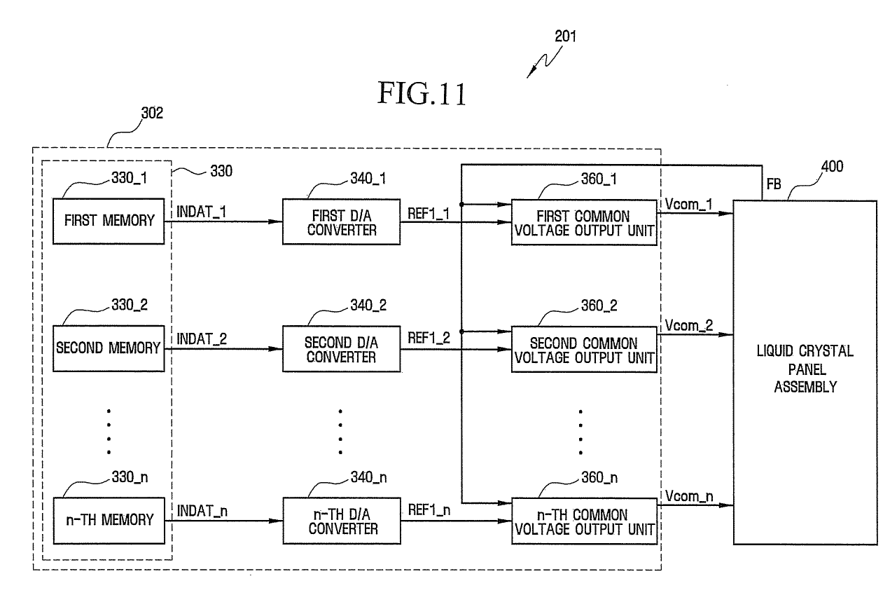

FIG. 10 is a block diagram illustrating another exemplary embodiment of a display system 11 according to the present invention. Similar components are represented by the same reference numerals and the descriptions thereof will be omitted for convenience of the explanation.

Referring to FIG. 10, unlike the previously described exemplary embodiment, the driving IC 301 includes a parallel interface unit 321. For example, as shown in FIG. 10, in case of n reference voltage output units 350_1 to 350_{—}n which function as slaves, an external signal supply device 101 supplies external data signals EXDAT_1 to EXDAT_n to the n reference voltage output units 350_1 to 350_{—}n, respectively, through n parallel data lines PDL_1 to PDL_n.

That is, the interface unit 321 includes a plurality of parallel data lines PDL_1 to PDL_n and a plurality of counters 311_1 to 311_{—}n and transmits the external data signals EXDAT_1 to EXDAT_n supplied from the external signal supply device 101 to the plurality of reference voltage output units 350_1 to 350_{—}n through the plurality of parallel data lines PDL_1 to PDL_n.

The counters 311_1 to 311_{—}n respectively receive and convert the external data signals EXDAT_1 to EXDAT_n into a plurality of internal data signals INDAT_1 to INDAT_n, and supply the converted internal data signals INDAT_1 to INDAT_n to the first reference voltage output units 350_1 to 350_{—}n. Here, when each of the external data signals EXDAT_1 to EXDAT_n is a pulse train which has both high levels and low levels on the basis of a predetermined voltage, each of the counters 311_1 to 311_{—}n may be an up/down counter which increments by counting the high levels or decrements by counting the low levels.

However, the counters 311_1 to 311_{—}n are not limited to the up/down counters, but may be implemented in various forms. In one exemplary embodiment each of the counters 311_1 to 311_{—}n may be a down counter which decrements by one or an up counter which increments by one while counting external data signals EXDAT_1 to EXDAT_n in a high level.

The display system 11 including the interface unit 321 can easily adjust the common voltages Vcom_1 to Vcom_n using the external signal supply device 101 and can improve display quality.

FIG. 11 is a block diagram showing another exemplary embodiment of a liquid crystal display device according to the present invention. The same reference numerals are used for similar parts as those shown in FIG. 1 and the descriptions thereof will be omitted for convenience of the explanation.

Referring to FIG. 11, the liquid crystal display device 201 includes a liquid crystal panel assembly 400 and a driving device 302. The driving device 302 includes a memory unit 330, one or more digital/analog converters 340_1 to 340_{—}n, and one or more common voltage output units 360_1 to 360_{—}n.

In the display systems 10 and 11 (see FIGS. 1 and 10) according to the exemplary embodiments of the invention, when the common voltages Vcom_1 to Vcom_n are adjusted to prevent the flicker from being generated, the external signal supply devices 100 and 101 (see FIGS. 1 and 10) are removed. That is, the common voltages Vcom_1 to Vcom_n which do not generate the flicker are generated by converting the internal data signal INDAT stored in the memories 330_1 to 330_{—}n (see FIG. 6). Further, the interface unit 320 (see FIG. 1) of the driving IC 300 (see FIG. 1) may be removed.

Therefore, as shown in FIG. 11, the liquid crystal display device 201 includes a memory unit 330 which outputs predetermined internal data signals INDAT_1 to INDAT_n, one or more digital/analog converters 340_1 to 340_{—}n which receives the internal data signals INDAT_1 to INDAT_n from corresponding memories 330_1 to 330_{—}n and outputs analog-type-first reference voltages REF1_1 to REF1_{—}n, and common voltage output units 360_1 to 360_{—}n which receive and compare a voltage FB of the common electrode and each of the first reference voltages REF1_1 to REF1_{—}n, and outputs common voltages Vcom_1 to Vcom_n on the basis of the comparison result.

As described above, the driving IC, the liquid crystal display device, and the display system according to the exemplary embodiments of the present invention can reduce the flicker and distortion of the common electrodes, thereby improving display quality.

Although the present invention has been described in connection with the exemplary embodiments of the present invention, it will be apparent to those skilled in the art that various modifications and changes may be made thereto without departing from the scope and spirit of the present invention. Therefore, it should be understood that the above exemplary embodiments are not limited, but illustrative in all aspects.

What is claimed is:

1. A driving integrated circuit comprising:
an interface unit which receives an external data signal from an outside and outputs an internal data signal;
at least one reference voltage output unit which receives the internal data signal and outputs a first reference voltage corresponding to the internal data signal; and
at least one common voltage output unit which receives a first common voltage from an outside and the first reference voltage, compares the first reference voltage and the first common voltage, and outputs a second common voltage based on the comparison result.

2. The driving IC of claim 1, wherein the interface unit is a serial digital interface.

3. The driving IC of claim 2, wherein the interface unit is an inter integrated circuit.

4. The driving IC of claim 1, wherein each of the reference voltage output units comprises a digital to analog converter which converts the data signal into the first reference voltage, wherein the first reference voltage is an analog voltage.

5. The driving IC of claim 1, wherein each of the reference voltage output units comprises a memory which stores the data signal, and a digital to analog converter which converts the data signal into the first reference voltage, wherein the first reference voltage is an analog voltage.

6. The driving IC of claim 1, wherein each of the common voltage output units comprises an operation amplifier.

7. The driving IC of claim 1, wherein each of the common voltage output units comprises:
a capacitor which receives the first common voltage and outputs an alternating current second reference voltage; and
an operation amplifier which amplifies a difference between the first reference voltage and the second reference voltage.

8. A liquid crystal display device comprising:
a liquid crystal panel assembly which comprises a first substrate which includes a pixel electrode and a second substrate which includes a common electrode; and
a driving unit which comprises a memory which outputs an internal data signal, a digital to analog converter which receives the internal data signal and outputs a first reference voltage corresponding to the internal data signal, and at least one common voltage output unit which receives the voltage of the common electrode, compares the first reference voltage and the voltage of the common electrode and outputs a common voltage based on the comparison result.

9. The liquid crystal display device of claim 8, wherein the first reference voltage corresponding to the internal data signal minimizes flicker.

10. The liquid crystal display device of claim 8, wherein each of the common voltage output units comprises:
a capacitor which receives the voltage of the common electrode and supplies a second reference voltage which has an alternating current; and
an operation amplifier which amplifies a difference between the first reference voltage and the second reference voltage.

11. A display system comprising:
an external signal supply device which supplies an external data signal; and
a liquid crystal display device which comprises a liquid crystal panel assembly including a first substrate on which pixel electrodes are formed and a second substrate on which a common electrode is formed, and a driving device comprising:
an interface unit which receives the external data signal and outputs an internal data signal;
at least one reference voltage output unit which receives the internal data signal and outputs a first reference voltage corresponding to the internal data signal; and
at least one common voltage output unit which receives the first reference voltage, compares the first reference voltage and a voltage of the common electrode, and outputs a common voltage based on the comparison result.

12. The display system of claim 11, wherein the interface unit is a serial digital interface.

13. The display system of claim 12, wherein the interface unit is an inter integrated circuit.

14. The display system of claim 13, wherein each of the reference voltage output units comprises:
a memory which receives and stores the internal data signal; and
a digital to analog converter which converts the internal data signal into the first reference voltage, wherein the first reference voltage is an analog voltage.

15. The display system of claim 13, wherein each of the common voltage output units comprises:
a capacitor which receives the voltage of the common electrode and supplies an alternating current second reference voltage; and
an operation amplifier which amplifies a difference between the first reference voltage and the second reference voltage.

16. The display system of claim 11, wherein the interface is a parallel interface.

17. The display system of claim 16, wherein the interface comprises at least one counter which counts the number of external data signals in at least one of a high level and a low level and converts the external data signal into the internal data signal.

18. The display system of claim 16, wherein each of the first reference voltage output units comprises a digital to analog converter which converts the internal data signal into the first reference voltage, wherein the first reference voltage is an analog voltage.

19. The display system of claim 18, wherein each of the first reference voltage output units further comprises a memory which stores the internal data signal.

20. The display system of claim 16, wherein each of the common voltage output units comprises:
a capacitor which receives the voltage of the common electrode and supplies an alternating current second reference voltage; and
an operation amplifier which amplifies a difference between the first reference voltage and the second reference voltage.

21. A method of driving an integrated circuit, the method comprising:
converting an external data signal to an internal data signal and providing the internal data signal to at least one reference voltage output unit;
converting the internal data signal to a first reference voltage and outputting the first reference voltage to at least one common voltage output unit;
comparing the first reference voltage and a voltage from a common electrode; and
outputting a common voltage based on the comparison result.
